(19) United States
(12) Patent Application Publication
(10) Pub. No.: US 2010/0109787 A1
(43) Pub. Date: May 6, 2010

(54) METHOD AND APPARATUS FOR OSCILLATOR STABILITY VERIFICATION

(75) Inventors: Kin Yee Wong, Ottawa (CA); Peter Roberts, Stittsville (CA)

Correspondence Address: Kramer & Amado, P.C., 1725 Duke Street, Suite 240, Alexandria, VA, 22314, US

(73) Assignee: ALCATEL LUCENT, Paris (FR)

(21) Appl. No.: 12/263,038

(22) Filed: Oct. 31, 2008

(51) Int. Cl. G01R 23/00

(52) U.S. Cl. 331/44

(57) ABSTRACT

A technique for oscillator stability and accuracy verification involves analysis of parameters from a plurality of phase locked loops (PLLs). During testing, each PLL receives a stable reference clock to identify variations in its clock oscillator. Mathematical calculations on the data extracted from each PLL permit identification of clock oscillators having undesirable timing characteristics. Remedial measures may then be implemented to correct problems with any faulty oscillators.

### TECHNICAL FIELD

Various exemplary embodiments relate generally to verification of oscillator stability in communication networks and, more particularly, to identifying defective clock oscillators by comparing generated clock frequencies.

### BACKGROUND

Stable clock frequencies have become increasingly important for communication networks. In particular, computer sites may rely on a backhaul network to provide synchronous interfaces for the proper delivery of data. These sites may rely upon network interfaces to derive stable timing references. A common method for deriving the timing references is to use phase-locked loop (PLL) technology. PLLs may use a digitally controlled oscillator (DCO) circuit that can adjust the frequency provided by a local oscillator in order to generate a frequency that matches the frequency of the network interface. These digital PLLs (DPLLs) are impacted by the stability of both the reference frequency from the network interface and the stability of the local oscillator. In order to ensure that the DPLL derives the optimal frequency, the performance of the local oscillators must be monitored and verified.

Traditionally, oscillators are tested during fabrication, but this testing may be limited in duration and may not exactly replicate the environmental conditions seen when the oscillator is used within a network element in a specific deployment. In order to test the performance of an oscillator in a deployment, dedicated test gear is required at the deployment site, in addition to a separate known good reference frequency used to test the oscillator stability. This testing may also be invasive, requiring significant time and operational planning to execute.

It would be desirable to implement a non-invasive technique that can be initiated remotely without requiring dedicated test gear. Testing in situ allows the performance of the oscillators to be derived, including any effects that can be triggered by vibrations or thermal conditions in the environment. When oscillators are tested today, their output frequency is compared against a known good reference and the difference is monitored either as a frequency deviation or as a phase deviation. This deviation is then processed mathematically to look for trends in the oscillator's frequency that then gives an indication of its stability.

Historically, Allan variance has been used as a measure of stability in clocks and oscillators. One may calculate Allan variance for a given oscillator by taking an average of the squares of the differences between successive readings of the fractional frequency error or phase error sampled over a particular testing period. In general, Allan variance, σ_{y}²(τ), involves variance of at least two samples according to the following equation:

$${σ}_{y}^{2} ( τ ) = \frac{1}{2} 〈 {( {y}_{n + 1} - {y}_{n} )}^{2} 〉 ,$$

where yₙ is a normalized frequency departure for particular testing periods, n, and τ represents the length of each testing period, n.

For oscillators that are vulnerable to drift, variance calculations may involve at least three samples. In such cases, because the Allan variance equation may lead to inaccurate calculations, analysts substitute the Hadamard variance, HVAR(τ). The Hadamard variance may be calculated according to the following equation:

$$HVAR ( τ ) = \frac{1}{6} 〈 {( {y}_{n + 2} - 2 {y}_{n + 1} + {y}_{n} )}^{2} 〉$$

Oscillators may also produce signals corrupted by noise that cannot be identified during short periods, as described above for jitter testing. Such noise may be associated with the physical environment, involving factors including vibration, shock, and temperature. Peripheral components coupled to the oscillator may also cause abrupt step-changes in frequency that might not be noticed by traditional stability tests that analyze usual measurements of variance values.

Accordingly, there is a need to test for such variations, particularly frequency changes that may be caused by temperature fluctuations or aging of the oscillator. As oscillators are frequently used in routing technologies, there is also a need for a technique that could be used with minimal disruption to system performance. There is also a need for a testing technique that could quickly identify a clock oscillator with timing problems that occur at irregular intervals or relatively low frequencies.

### SUMMARY

In light of the present need for clock oscillator testing, a brief summary of various exemplary embodiments is presented. Some simplifications and omissions may be made in the following summary, which is intended to highlight and introduce some aspects of the various exemplary embodiments, but not to limit the scope of the invention. Detailed descriptions of a preferred exemplary embodiment adequate to allow those of ordinary skill in the art to make and use the inventive concepts will follow in later sections.

In various exemplary embodiments, a method for oscillator stability and accuracy verification may comprise: generating a reference clock signal with a reference clock generator; applying the reference clock signal to a plurality of Phase Locked Loop (PLLs), wherein each of the PLLs comprises a filter and a digitally-controlled oscillator (DCO) coupled to a clock oscillator; determining, for each of the PLLs, a parameter used to adjust said DCO; analyzing the parameters for the PLLs to identify any of the parameters that are outside of an acceptable range; identifying a corresponding clock oscillator as defective for each parameter outside of the acceptable range; and applying a remedial measure to the defective clock oscillator.

In various exemplary embodiments, the method may further comprise calculating standard deviation values for the parameters. Alternatively, the method may further comprise calculating rates of change for the parameters. In another embodiment, the method may perform statistical analysis to identify any of the parameters that are statistical outliers. This statistical analysis may consider at least a standard deviation for each of the parameters.

In various exemplary embodiments, the method may further comprise notifying a network operator of all clock oscillators that are defective. Alternatively, the method may further comprise selecting a replacement oscillator for each defective clock oscillator.

In various exemplary embodiments, analysis of the parameters may occur substantially simultaneously for all of the PLLs. Alternatively, analysis of the parameters may occur in a round robin schedule, having an equal period of time assigned to analysis of the parameters from each of the PLLs.

In various exemplary embodiments, system for oscillator stability and accuracy verification may comprise a reference clock generator that produces a reference clock; a plurality of Phase Locked Loop (PLLs), each of the PLLs receiving the reference clock and comprising a filter and a digitally-controlled oscillator (DCO) coupled to a clock oscillator; a collector that aggregates parameters used to adjust the DCO, for each of the PLLs; an analyzer that compares the parameters to identify any of the parameters that are outside of an acceptable range; a detector that identifies clock oscillators corresponding to any of the parameter outside of said acceptable range as defective; and an alarm unit that initiates application of a remedial measure to the defective clock oscillators.

In various exemplary embodiments, the analyzer may further comprise a statistical unit that calculates standard deviation values for the parameters. Alternatively, the analyzer may further comprise a statistical unit that calculates rates of change for the parameters. In another exemplary embodiment, the analyzer may comprise a statistical unit that identifies any of the parameters that are statistical outliers. This statistical unit may consider at least a standard deviation for each of the parameters.

In various exemplary embodiments, the alarm unit may further comprise a transmitter that notifies a network operator of all clock oscillators that are defective. Alternatively, the alarm unit may further comprise a substitution unit that selects a replacement oscillator for each defective clock oscillator.

In various exemplary embodiments, the collector may operate substantially simultaneously for all of the PLLs. Alternatively, the collector may operate according to a round robin schedule, having an equal period of time assigned to aggregation of parameters from each of the PLLs.

In various exemplary embodiments, a method for oscillator stability and accuracy verification, may comprise generating a plurality of clock signals with a plurality of clock oscillators; applying the plurality of clock signals in series to a Phase Locked Loop (PLL), wherein the PLL comprises a filter and a digitally-controlled oscillator (DCO) coupled to a reference clock generator that produces a reference clock signal; determining, for each of the plurality of clock signals applied to the PLL, a parameter used to adjust the DCO; and analyzing the parameters for each of the plurality of clock signals to identify any of the parameters that are outside of an acceptable range; identifying a corresponding clock oscillator as defective for each parameter outside of the acceptable range; and applying a remedial measure to the defective clock oscillator. The plurality of clock signals may respectively correspond to a plurality of central clock sub-systems.

### BRIEF DESCRIPTION OF THE DRAWINGS

In order to better understand various exemplary embodiments, reference is made to the accompanying drawings, wherein:

FIG. 1 is a schematic diagram of an exemplary system for forwarding data over a communication network, the system including synchronization components;

FIG. 2 is a schematic diagram of a first exemplary timing module for use in the system of FIG. 1;

FIG. 3 is a schematic diagram of a second exemplary timing module for use in the system of FIG. 1;

FIG. 4 is a schematic diagram of a third exemplary timing module for use in the system of FIG. 1;

FIG. 5 is a schematic diagram of an exemplary phase locked loop (PLL) for use in the modules of FIG. 2 and FIG. 3;

FIG. 6 is a schematic diagram of an exemplary phase locked loop (PLL) for use in the module of FIG. 4;

FIG. 7 is a schematic diagram of an exemplary analyzer for use in the modules of FIGS. 2-4;

FIG. 8 is a flow chart of an exemplary method for monitoring timing information that corresponds to the modules of FIG. 2 and FIG. 3; and

FIG. 9 is a flow chart of an exemplary method for monitoring timing information that corresponds to the module of FIG. 4.

### DETAILED DESCRIPTION

Referring now to the drawings, in which like numerals refer to like components or steps, there are disclosed broad aspects of various exemplary embodiments.

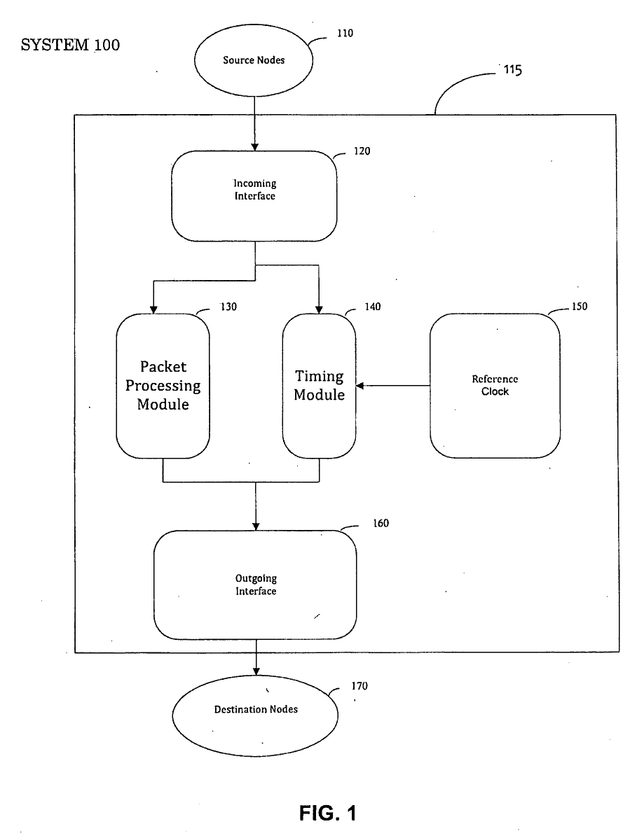

FIG. 1 is a schematic diagram of an exemplary system 100 for forwarding data over a communication network, the system 100 including synchronization components. Exemplary system 100 comprises source nodes 110, a network element 115 comprising an incoming interface 120, a data processing module 130, a timing module 140, a reference clock 150, an outgoing interface 160, and destination nodes 170.

Source nodes 110 may be, for example, network elements used to forward data over a network. Signals from source nodes 110 flow into incoming interface 120 at unpredictable intervals. Thus, it may be important for the network element 115 to synchronize processing of data received from source nodes 110. For example, synchronization may be necessary when sending and receiving data over a Time-Division Multiplexed (TDM) pseudowire or when otherwise emulating a circuit-switched path. This synchronization process may involve data processing module 130 and timing module 140.

Data processing module 130 may be hardware and/or software implemented on a computer-readable storage medium that processes incoming data received at incoming interface 120. Thus, data processing module 130 may operate, for example, according to Transmission Control Protocol/Internet Protocol (TCP/IP), Multi Protocol Label Switching (MPLS), Ethernet, Provider Backbone Transport (PBT), or any other suitable protocol that will be apparent to those of skill in the art. Data processing module 130 may be coupled to timing module 140 in order to obtain proper synchronization of the data.

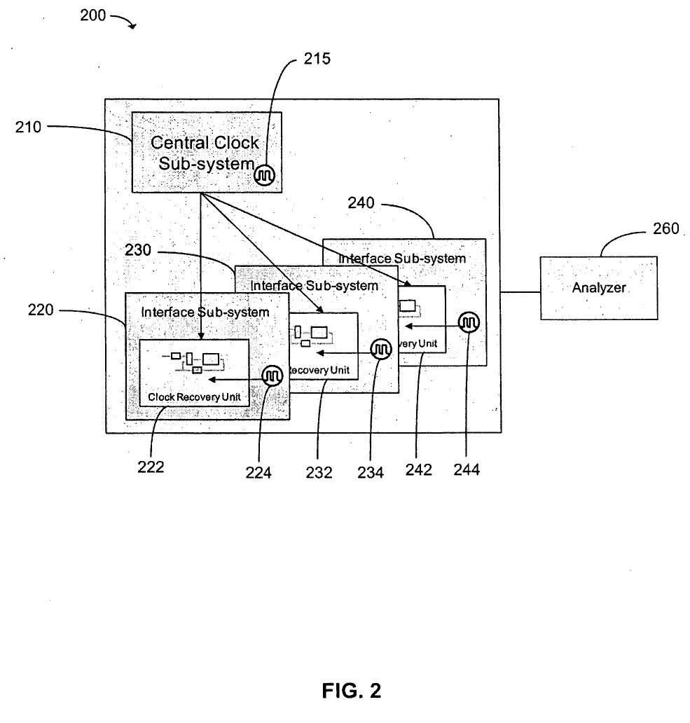

Timing module 140 may be hardware and/or software implemented on a computer-readable storage medium. Timing module may include a plurality of oscillators to generate internal clocks for network element 115. These internal clocks may be generated, for example, by a plurality of digital phase locked loops (PLLs). The PLLs generate a clock signal that has a fixed relationship to the phase of a reference clock. The internal components of exemplary timing modules 140 are described in further detail below with reference to FIGS. 2-4.

In various exemplary embodiments, reference clock 150 distributes timing information to timing module 140, thereby synchronizing the operation of any elements within timing module 140. Reference clock 150 may be obtained from an external source, distant from timing module 140. Reference clock 150 may also use any suitable timing mechanism that will be apparent to those of skill in the art.

More specifically, reference clock 150 may access an external clock, such as a Global Positioning Satellite (GPS) or an atomic clock. In addition, node 115 may receive a Stratum 1 reference clock from another network element over a Layer 1 interface, such as SONET, T1, or E1/SDH. Alternatively, reference clock 150 may itself maintain a highly accurate clock, thereby eliminating the need to retrieve the value from an external source. After determining the current clock value, reference clock 150 may generate a numerical value indicating a particular frequency, thereby defining a reference clock frequency.

Outgoing interface 160 may receive data from data processing module 130. This data may flow into outgoing interface 160 at rates synchronized by timing module 140. Upon leaving the network element 115, data may flow from outgoing interface 160 to destination nodes 170.

FIG. 2 is a schematic diagram of a first exemplary timing module 200 for use in the system of FIG. 1. Exemplary module 200, which may be hardware and/or software implemented on a computer-readable storage medium, comprises a reference clock generator 215 in a central clock sub-system (CCSS) 210, a first interface sub-system (ISS) 220 comprising a first clock recovery unit (CRU) 222 and a first clock oscillator 224, a second ISS 230 comprising a second CRU 232 and a second clock oscillator 234, a third ISS 240 comprising a third CRU 242 and a second clock oscillator 244, and an analyzer 260.

Reference clock generator 215, as described above, may provide a stable external reference clock. To maintain end-to-end quality of service (QoS) in a router, reference clock generator 215 may provide adaptive clock recovery (ACR) timing during operations, administration, and maintenance (OAM) periods. Other features provided by reference clock generator 215 may include line timing and Ethernet synchronization. Reference clock generator 215 may also use a built-in Stratum 3 clock to assist in synchronization maintenance when a primary source is unavailable.

An American National Standards Institute (ANSI) standard defines various strata and minimum performance requirements for digital network synchronization. Typical examples of Stratum 2 clocks are Rubidium Standards and Double Oven Controlled Crystal Oscillators (OCXOs). Stratum 3 clocks resemble Stratum 2 clocks, but have a wider operating range for frequency accuracy and stability. In general, a Stratum 3 clock system requires a minimum adjustment (tracking) range of 4.6×10⁻⁶. The short term drift of the system should be less than 3.7×10⁻⁷ in 24 hours.

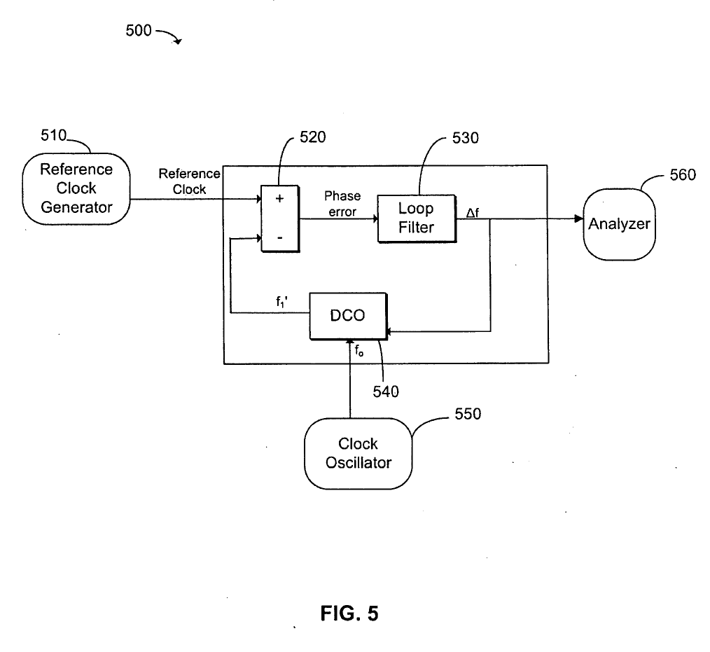

Module 200 may run a plurality of digital PLLs within the CRUs, 222, 232, and 242, having each digital PLL in a CRU correspond to a respective clock oscillator on the respective ISS, 224, 234, and 244. While exemplary module 200 has three oscillators, 224, 234, and 244, and three CRUs, 222, 232, and 242, alternative implementations of module 200 may have N oscillators and N PLLs, as will be apparent to those of ordinary skill in the art. The internal components of a digital PLL are described in further detail below with reference to FIG. 5.

In addition, in various exemplary embodiments, PLLs within the CRUs, 222, 232, and 242, may be coupled to an analyzer 260, which comprises hardware and/or software configured to process values gathered from each of the PLLs within the CRUs, 222, 232, and 242. Analyzer 260 may use data collected from the PLLs within the CRUs, 222, 232, and 242, to identify timing problems in the corresponding clock oscillators, 224,234, and 244. The internal components of an exemplary analyzer are described in further detail below with reference to FIG. 5.

During operation, CCSS 210 may configure each CRU 220, 230, 240 for testing. Next, analyzer 260 may monitor dynamic parameters from the PLL within each CRU 220, 230,240. Third, analyzer may show relative performance by comparing the dynamic parameters received from the PLL within each CRU 220, 230, 240.

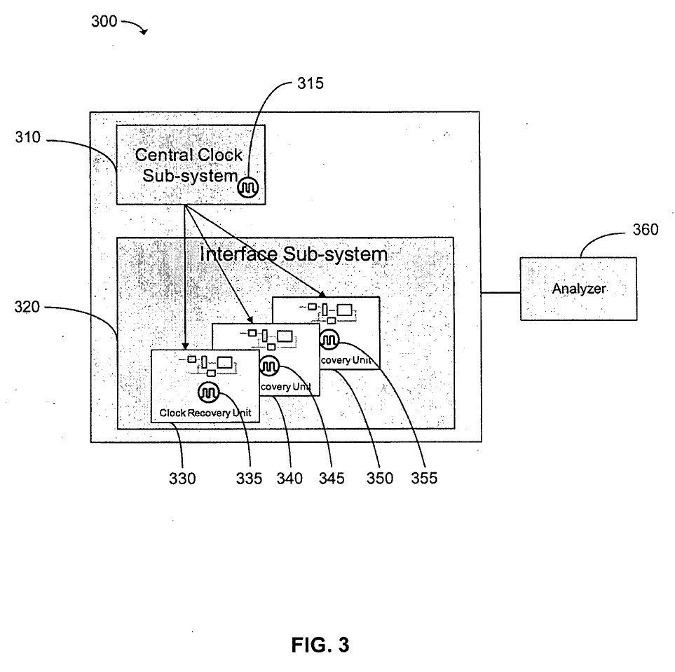

FIG. 3 is a second schematic diagram of an exemplary timing module 300 for use in the system of FIG. 1. Exemplary module 300, which may be hardware and/or software implemented on a computer-readable storage medium, comprises a reference clock generator 315 in a CCSS 310, an ISS 320 comprising a first CRU 330 and a first clock oscillator 335, a second CRU 340 and a second clock oscillator 345, a third CRU 350 and a third clock oscillator 345, and an analyzer 360.

Module 300 may be similar in operation to module 200, as described above. However, while module 200 may have a plurality of ISS units, 220, 230, and 240, module 300 may have only one ISS unit, 320. Thus, each CRU, 222, 232, and 242, in module 200 may share a single oscillator, in which case the oscillators, 224, 234, and 244, of module 200, may be the same. In contrast, each CRU, 330, 340, and 350, in module 300, may have a separate oscillator, 335, 345, and 355.

During operation, CCSS 310 may configure each CRU 330, 340, 350 for testing. Second, analyzer 360 may monitor dynamic parameters from the PLL within each CRU 330, 340, 350. Third, analyzer 360 may determine the relative performance by comparing the dynamic parameters and thereby isolate faulty oscillators.

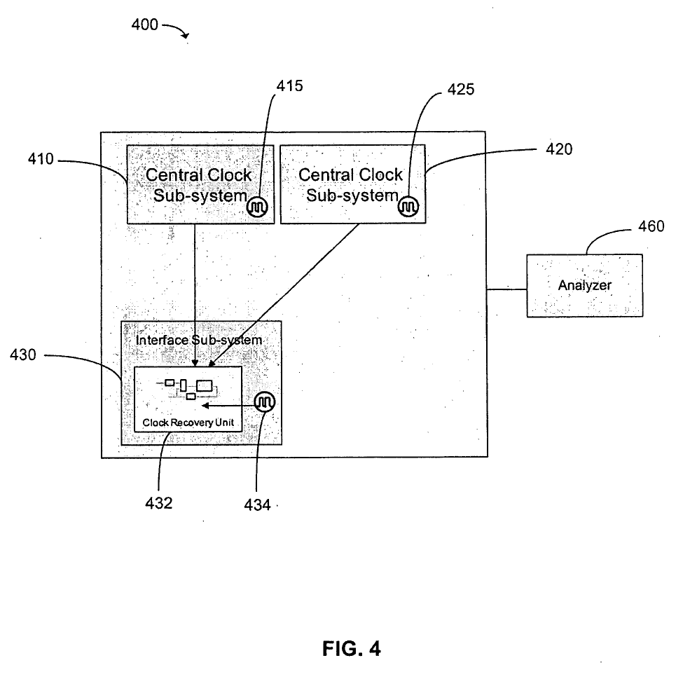

FIG. 4 is a third schematic diagram of an exemplary timing module 400 for use in the system of FIG. 1. Exemplary module 400, which may be hardware and/or software implemented on a computer-readable storage medium, comprises a first CCSS 410 having a first clock oscillator 415, a second CCSS 420 having a second clock oscillator 425, an ISS 430 having a CRU 432 and a reference clock generator 434, and an analyzer 460. The CCSS modules 410 and 420 operate in redundant fashion so that they nominally generate the same frequency for use by the interface Subsystem 430. However these frequencies rely on the oscillators 415 and 425 as part of the generation. These oscillators need validation.

Unlike the other modules, 200 and 300, module 400 involves testing of the clock oscillators, 415 and 425, within the CCSS units, 410 and 420. A testing procedure may involve configuration of a single CRU 432 using a clock signal from one CCSS 410. Analyzer 460 may monitor dynamic parameters from a PLL within CRU 432. The testing procedure may then repeat for additional CCSS units 420. Although two CCSS units, 410 and 420, are depicted in FIG. 4, N CCSS units may be tested, as may be apparent to one having ordinary skill in the art. As a result of this testing, analyzer 460 may show relative performance of the clock oscillator 415, 425 within each CCSS 410, 420 and thereby isolate faulty oscillators.

FIG. 5 is a schematic diagram of an exemplary PLL 500 for use in module 200 of FIG. 2 and in module 300 of FIG. 3. Exemplary PLL 500, which may be hardware or software implemented on a computer-readable storage medium, comprises a reference clock generator 510, a phase detector 520, a loop filter 530, a digitally controlled oscillator (DCO) 540, a clock oscillator 550, and an analyzer 560.

Digital PLL 500 receives a stable reference clock from reference clock generator 510. Application of this reference clock to phase detector 520 produces a phase error signal measuring the difference between the reference clock and the current clock frequency in PLL 500. An Adaptive Clock Recovery (ACR) algorithm may process timestamps within phase detector 520. After repeated feedback cycles through phase detector 520, the phase error signal may gradually drop toward zero, as the frequency of PLL 500 approaches the reference clock frequency.

Loop filter 530 provides a mechanism to train the loop to a value for the frequency adjustment parameter, designated by Δf in FIG. 5, for the DCO 540. This value may be a fixed number of bits and may approach a constant value when stabilized. For statistical analysis, analyzer 560 obtains data from this section of PLL 500 to obtain useful data parameters.

DCO 540 may receive a signal from a clock oscillator 550 having a frequency fₒ. DCO 540 may then may mix this signal with the frequency adjustment parameter Δf from loop filter 530. Therefore, the output from DCO 540 may have a new frequency f₁′ that combines fₒ and Δf. If fₒ varies due to temperature changes or other environmental factors, PLL 500 may not provide a reliable clock.

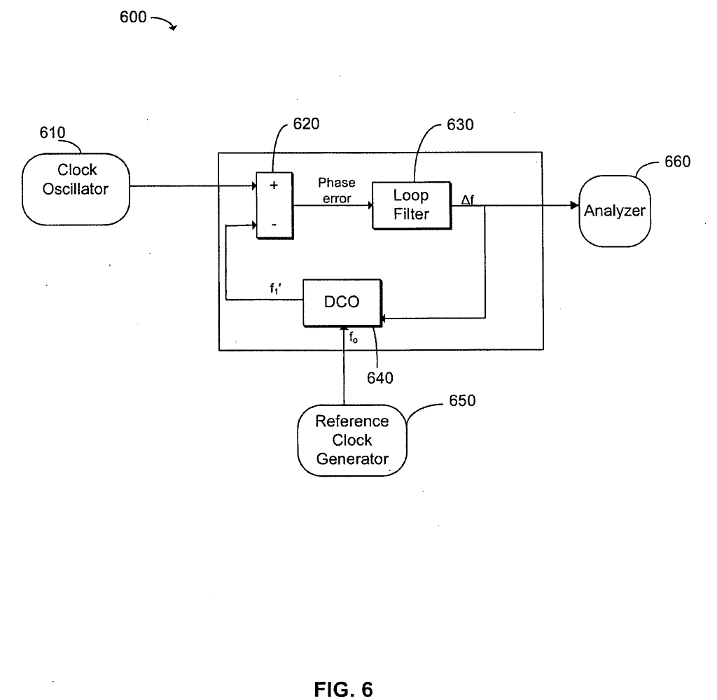

FIG. 6 is a schematic diagram of an exemplary PLL 600 for use in module 400 of FIG. 4. Exemplary PLL 600, which may be hardware or software implemented on a computer-readable storage medium, comprises a clock oscillator 610, a phase detector 620, a loop filter 630, a digitally controlled oscillator (DCO) 640, a reference clock generator 650, and an analyzer 660. PLL 600 resembles PLL 500 in operation other than having exchanged positions of its clock oscillator 610 and reference clock generator 650.

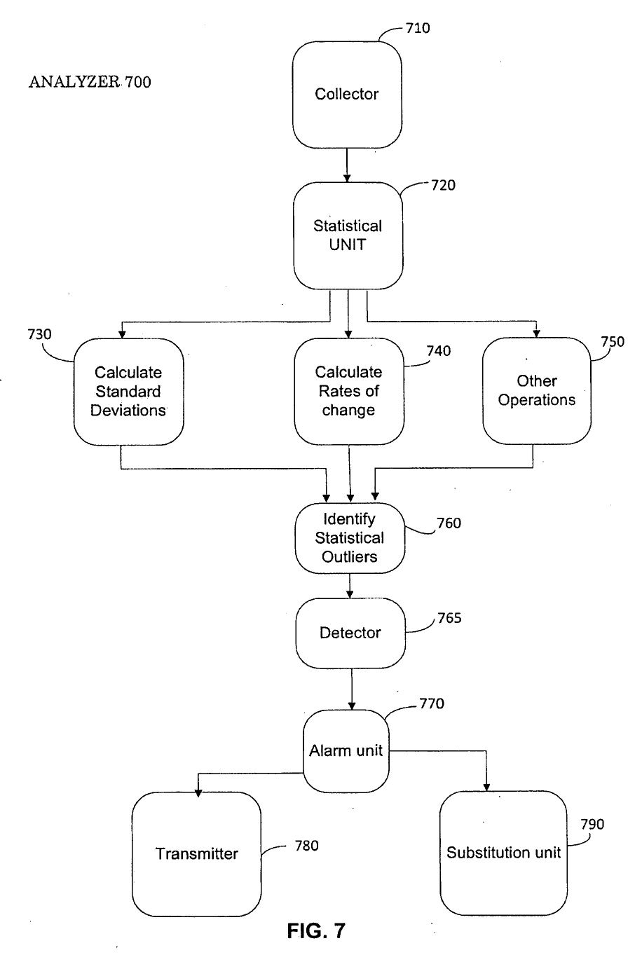

FIG. 7 is a schematic diagram of an exemplary analyzer 700 for use in the modules, 200, 300, and 400, of FIGS. 2-4. Exemplary analyzer 700, which may be hardware and/or software implemented on a computer-readable storage medium, comprises a collector 710, a statistical unit 720, a module that calculates standard deviations 730, a module that calculates rates of change 740, a module that performs other operations 750, a module that identifies statistical outliers 760, a detector 765, an alarm unit 770, a transmitter 780, and a substitution unit 790.

Collector 710, which may be hardware and/or software implemented on a computer-readable storage medium, may obtain parameters for analysis from digital PLLs within CRUs. These parameters may represent digital frequency adjustments and may be quantized into specific groups of bits. Collector 710 may need to sample a particular subset of these bits during designated testing periods to obtain data for subsequent analysis. In general, collector 710 may continue to aggregate parameters for any period desired in order to ensure that sufficient data is available for subsequent analysis.

Collector 710 may also obtain data, in parallel, from a plurality of CRUs, such as the CRUs 330, 340, 350 in FIG. 3. Collector 710 may also obtain data, in series, from repeated tests performed on a single CRU, such as CRU 432 in FIG. 4. In one embodiment, collector 710 may obtain data from each PLL in parallel, such that collector 710 receives the data substantially simultaneously. Alternatively, collector 710 may operate according to a round robin schedule, having an equal period of time assigned to aggregation of parameters.

Data from collector 710 may flow into statistical unit 720, where various mathematical calculations may be performed. As one option, statistical unit 720 may send data to module 730 for calculation of standard deviations. As another option, statistical unit 720 may send data to module 740 for calculation of relative rates of change. As yet another option, statistical unit 720 may use a module 750 to perform other operations. All of these modules, 730, 740, and 750, may be hardware and/or software implemented on a computer-readable storage medium.

In general, a standard deviation is a measure of the dispersion of a collection of values. Module 730 may define a standard deviation for the data from collector 710 as the square root of a variance, wherein the variance may be an Allan variance, a Hadamard variance, or another variance deemed suitable by one of ordinary skill in the art. Module 730 may compare standard deviation values to identify a PLL having an extreme value. This identification may then be sent to detector 765 for subsequent operations related to identifying defective clock oscillators.

Module 740 may compare data from collector 710 to find the relative rates of change. While clock oscillators that respectively correspond to the PLLs may not operate at the same frequency, the PLLs should respond to the application of the reference clock in a similar manner. Basically, the oscillators may have the same nominal performance, a pattern than may be true for line modules of a network element. If factors obtained from one PLL shift abruptly, this may signify defective operation of one of the clock oscillators. Such data may be forwarded to detector 760.

Module 750 may review data from collector 710 in other ways. For example, if frequency characteristics from a large group of PLLs follow a Gaussian distribution, module 750 might examine the tails of the bell shaped curve. Module 750 may then identify the PLLs that produced parameters corresponding to extreme deviations from the median in the probability distribution. Alternatively, module 750 might use standardized moments for the probability distribution, such as measurements of skewness or kurtosis, to spot unusual values in irregular probability distributions that featured lopsided or asymmetric data sets. Testing may also involve voting or mean analysis of variation in DCO values.

Processed data from the statistical modules, 730, 740, and 750, may then enter a unit 760 that identifies statistical outliers. Detector 765 may correlate the information from statistical outlier unit 760 to identify the PLLs that produced abnormal data. Detector 765 may then correlate the list of defective PLLs to a corresponding list of clock oscillators. Having assembled a list of defective clock oscillators as a result of this step, detector 765 may then send the defective clock oscillator list to alarm unit 770.

After identifying clock oscillators that are experiencing timing problems, analyzer 700 may use alarm unit 770 to implement remedial measures for these clock oscillators. For example, alarm unit 770 may use transmitter 780 to send a message to a computer system or a network operator to identify the problematic clock oscillators. Alternatively, substitution unit 790 may notify a computer system or network operator that the defective clock oscillators should be replaced with oscillators that provide accurate timing information. This replacement could be implemented in real-time utilizing redundant oscillators for each PLL. Other appropriate remedial measures will be apparent to those of ordinary skill in the art.

In various exemplary embodiments, transmitter 780 may be an interface comprising hardware and/or software configured to send information to an operation support system. Thus, transmitter 780 could be configured to send a report identifying all of the clock oscillators that are experiencing timing problems, raise an alarm in the network, or transmit any other data needed to implement a remedial measure to address the timing problems.

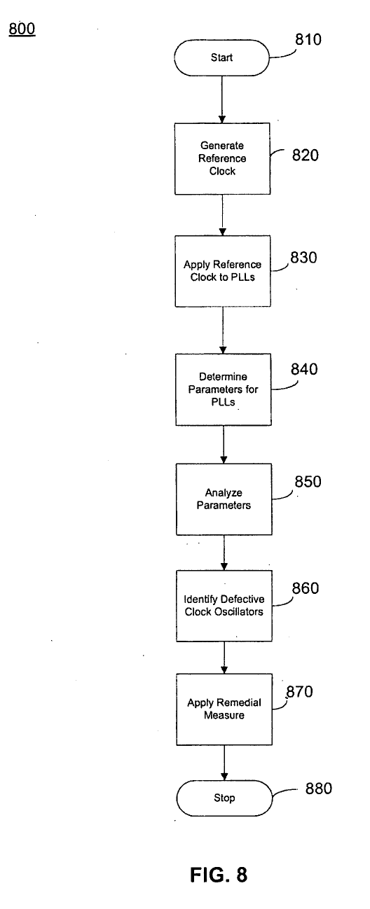

FIG. 8 is a flow chart of a first exemplary method 800 for oscillator stability and accuracy verification in a plurality of clock oscillators in ISS units.

Exemplary method 800 starts in step 810 and proceeds to step 820. Step 820 involves generation of a reference clock in ISS units, as shown in FIGS. 2 and 3. This generation step may either occur within a network element, such as a router, or may occur in an external source. If the reference clock is external, step 820 may involve an interface that receives the reference clock in a timing module 140, as shown in FIG. 1.

In step 830, the generated reference clock is applied to a plurality of PLLs. This method may be applied to N PLLs, so long as step 830 applies the reference clock to each PLL in the same way. This method is designed to analyze the performance of clock oscillators, devices under test (DUT), as variables. Thus, the reference clock may act as a constant.

In step 840, the method determines parameters for the PLLs. As shown in FIG. 5, these parameters may be obtained from a loop filter 530 within a digital PLL. Parameters may be obtained from other locations within the digital PLL, as may be apparent to those of ordinary skill in the art.

In step 850, the parameters obtained in step 840 are analyzed. As shown in FIG. 7, analysis step 850 may involve various calculations linked to statistical unit 720. In particular, parameters may be tested for aberrant standard deviations 730, unusual rates of change 740, and other abnormal statistical patterns 750.

In step 860, results from the analysis in step 850 may be used to identify defective clock oscillators. As shown in FIG. 7, step 860 may be performed within detector 760. Step 860 may correlate statistical results from particular PLLs to alert alarm unit 770 with a list of defective clock oscillators.

In step 870, the method may apply a remedial measure to the defective clock oscillators. As shown in FIG. 7, this remedial measure may involve use of a transmitter to notify a network operator of timing problems in a clock oscillator. Alternatively, step 870 may activate substitution unit 790, replacing a defective clock oscillator with an oscillator having proper timing characteristics.

Exemplary method 800 stops in block 880.

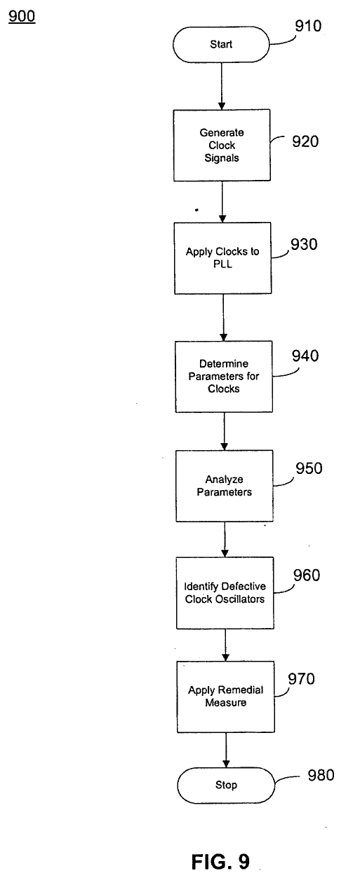

FIG. 9 is a flow chart of a second exemplary method 900 for oscillator stability and accuracy verification in a plurality of clock oscillators in CCSS units. Exemplary method 900 starts in step 910 and proceeds to step 920. Step 920 involves generation of clock signals. This generation step may occur within a plurality of CCSS units, 410 and 420, as shown in FIG. 4. The generation may be directly from the clock oscillators, 415 and 425, or may be from sub-modules using the two oscillators as part of the generation, for example using DPLLs. While two clock signal generators are shown in FIG. 4, may involve generation of N clock signals, as may be apparent to one having ordinary skill in the art.

In step 930, the clock signals are applied to a PLL that has a reliable reference clock signal. This method is designed to analyze the performance of clock oscillators, 415 and 425, as devices under test (DUT). Thus, the reference clock within the PLL may act as a constant.

In step 940, the method determines parameters for the PLLs. As shown in FIG. 6, these parameters may be obtained from a loop filter 630 within a digital PLL. Parameters may be obtained from other locations within the digital PLL, as may be apparent to those of ordinary skill in the art.

In step 950, the parameters obtained in step 940 are analyzed. As shown in FIG. 7, analysis step 950 may involve various calculations linked to statistical unit 720. In particular, parameters may be tested for aberrant standard deviations 730, unusual rates of change 740, and other abnormal statistical patterns 750.

In step 960, results from the analysis in step 950 may be used to identify defective clock oscillators. As shown in FIG. 7, step 960 may be performed within detector 760. Step 960 may correlate statistical results from particular PLLs to alert alarm unit 770 with a list of defective clock oscillators.

In step 970, the method may apply a remedial measure to the defective clock oscillators. As shown in FIG. 7, this remedial measure may involve use of a transmitter to notify a network operator of timing problems in a clock oscillator. Alternatively, step 970 may activate substitution unit 790, replacing a defective clock oscillator with an oscillator having proper timing characteristics.

Exemplary method 900 stops in block 980.

It should be further apparent from the foregoing description that various exemplary embodiments of the invention may be implemented in hardware, firmware, and/or software. Furthermore, various exemplary embodiments may be implemented as instructions stored on a machine-readable storage medium, which may be read and executed by at least one processor to perform the operations described in detail herein.

A machine-readable storage medium may include any mechanism for storing or transmitting information in a form readable by a machine, such as a computer. Thus, a machine-readable storage medium may include a read-only memory (ROM), a random-access memory (RAM), a magnetic disk storage medium, an optical storage medium, flash-memory devices, and similar storage media.

Although the various exemplary embodiments have been described in detail with particular reference to certain exemplary aspects thereof, it should be understood that the invention is capable of other embodiments and its details are capable of modifications in various obvious respects. As is readily apparent to those skilled in the art, variations and modifications may be implemented while remaining within the spirit and scope of the invention. Accordingly, the foregoing disclosure, description, and figures are for illustrative purposes only and do not in any way limit the invention, which is defined only by the claims.

What is claimed is:

1. A method for oscillator stability and accuracy verification, said method comprising:
generating a reference clock signal with a reference clock generator;
applying said reference clock signal to a plurality of Phase Locked Loop (PLLs), wherein each of said PLLs comprises a filter and a digitally-controlled oscillator (DCO) coupled to a clock oscillator;
determining, for each of said PLLs, a parameter used to adjust said DCO; and
analyzing said parameters for said PLLs to identify any of said parameters that are outside of an acceptable range;
identifying a corresponding clock oscillator as defective for each parameter outside of the acceptable range; and
applying a remedial measure to said defective clock oscillator.

2. The method of claim 1, further comprising:
calculating standard deviation values for said parameters.

3. The method of claim 1, further comprising:
calculating rates of change for said parameters.

4. The method of claim 1, further comprising:
performing statistical analysis to identify any of said parameters that are statistical outliers.

5. The method of claim 4, wherein said statistical analysis considers at least a standard deviation for each of said parameters.

6. The method of claim 1, further comprising:
notifying a network operator of all clock oscillators that are defective.

7. The method of claim 1, further comprising:
selecting a replacement oscillator for each defective clock oscillator.

8. The method of claim 1, wherein analyzing said parameters occurs substantially simultaneously for all of said PLLs.

9. The method of claim 1, wherein analyzing said parameters occurs in a round robin schedule, having an equal period of time assigned to analysis of parameters from each of said PLLs.

10. A system for oscillator stability and accuracy verification, the system comprising:
a reference clock generator that produces a reference clock;
a plurality of Phase Locked Loop (PLLs), each of said PLLs receiving said reference clock and comprising a filter and a digitally-controlled oscillator (DCO) coupled to a clock oscillator;
a collector that aggregates parameters used to adjust said DCO, for each of said PLLs;
an analyzer that compares said parameters to identify any of said parameters that are outside of an acceptable range;
a detector that identifies a clock oscillator corresponding to said parameter outside of said acceptable range as defective; and
an alarm unit that initiates application of a remedial measure to said defective clock oscillator.

11. The system of claim 10, wherein said analyzer further comprises:
a statistical unit that calculates standard deviation values for said parameters.

12. The system of claim 10, wherein said analyzer further comprises:
a statistical unit that calculates rates of change for said parameters.

13. The system of claim 10, wherein said analyzer further comprises:
a statistical unit that identifies any of said parameters that are statistical outliers.

14. The system of claim 13, wherein said statistical unit considers at least a standard deviation for each of said parameters.

15. The system of claim 10, wherein said alarm unit further comprises:
a transmitter that notifies a network operator of all clock oscillators that are defective.

16. The system of claim 10, wherein said alarm unit further comprises:
a substitution unit that selects a replacement oscillator for each defective clock oscillator.

17. The system of claim 10, wherein said collector operates substantially simultaneously for all of said PLLs.

18. The system of claim 10, wherein said collector operates according to a round robin schedule, having an equal period of time assigned to aggregation of parameters from each of said PLLs.

19. A method for oscillator stability and accuracy verification, said method comprising:
generating a plurality of clock signals with a plurality of clock oscillators;
applying said plurality of clock signals in series to a Phase Locked Loop (PLL), wherein said PLL comprises a filter and a digitally-controlled oscillator (DCO) coupled to a reference clock generator that produces a reference clock signal;
determining, for each of said plurality of clock signals applied to said PLL, a parameter used to adjust said DCO; and
analyzing said parameters for each of said plurality of clock signals to identify any of said parameters that are outside of an acceptable range;
identifying a corresponding clock oscillator as defective for each parameter outside of the acceptable range; and
applying a remedial measure to said defective clock oscillator.

20. The method of claim 19, wherein said plurality of clock signals respectively correspond to a plurality of central clock sub-systems.
